(19) United States
(12) Patent Application Publication
(10) Pub. No.: US 2015/0130067 A1
(43) Pub. Date: May 14, 2015

(54) OHMIC CONTACT STRUCTURE AND SEMICONDUCTOR DEVICE HAVING THE SAME

(71) Applicants: Chien-Wei Chiu, Beigan Township (TW); Ting-Wei Liao, Taichung (TW); Chieh-Hsiung Kuan, Taipei (TW); Tsung-Yi Huang, Hsinchu (TW); Tsung-Yu Yang, Kaohsiung (US)

(72) Inventors: Chien-Wei Chiu, Beigan Township (TW); Ting-Wei Liao, Taichung (TW); Chieh-Hsiung Kuan, Taipei (TW); Tsung-Yi Huang, Hsinchu (TW); Tsung-Yu Yang, Kaohsiung (US)

(73) Assignee: RICHTEK TECHNOLOGY CORPORATION, ZHUBEI CITY (TW)

(21) Appl. No.: 14/076,768

(22) Filed: Nov. 11, 2013

(51) Int. Cl. H01L 29/41; H01L 29/45

(52) U.S. Cl. CPC H01L 29/41; H01L 29/45
USPC 257/773

(57) ABSTRACT

This invention provides an ohmic contact structure including: a semiconductor substrate having a top surface which includes a plurality of micro-structures; and a conductive layer, which is formed on the micro-structures. An ohmic contact is formed by the conductive layer and the semiconductor substrate. The present invention also provides a semiconductor device having the ohmic contact structure.

### BACKGROUND OF THE INVENTION

1. Field of Invention

The present invention relates to an ohmic contact structure and a semiconductor device having the ohmic contact, especially an ohmic contact structure having micro-structures so that the heat treatment temperature required for forming an ohmic contact is reduced, and a semiconductor device having the ohmic contact.

2. Description of Related Art

FIG. 1A shows a prior art ohmic contact structure 10 including a semiconductor substrate 11 and a conductive layer 13, wherein the semiconductor substrate 11 contains conductive impurities such as P-type or N-type impurities, and the conductive layer 13 is formed on the semiconductor substrate 11. An ohmic contact is formed by the conductive layer 13 and the semiconductor substrate 11. The conductive layer 13 can be made of a conductive material such as metal, metal compound, conductive polymer, or polysilicon, and it can be coupled to an external circuit.

According to this prior art, a high temperature thermal annealing step is used to form the ohmic contact between the conductive layer 13 and the semiconductor substrate 11, wherein the high temperature can be as high as 850° C. or even more (for example when the conductive layer is made of titanium or aluminum). The high temperature thermal annealing step could change the impurity distribution or the crystalline structure, to cause an unpredictable result. Therefore, the high temperature thermal annealing step causes an inconvenience in process integration, that is, any process which is sensitive to high temperature should be arranged later than the high temperature thermal annealing step. Besides, this prior art requires high temperature equipment, which has high cost and low throughput. In view of the above, the high temperature thermal annealing step causes a lot of inconveniences. It is desired to reduce the risk and inconveniences caused by the high temperature thermal annealing step while maintaining the ohmic contact quality formed by the conductive layer 13 and the semiconductor substrate 11.

### SUMMARY OF THE INVENTION

In one perspective of the present invention, an ohmic contact structure is provided. The ohmic contact structure includes a semiconductor substrate which includes a plurality of micro-structures on a top surface thereof, and a conductive layer formed on the micro-structures. An ohmic contact is formed by the conductive layer and the semiconductor substrate.

In one embodiment, the conductive layer comprises a basic layer and a buffer layer, wherein the buffer layer is formed on the semiconductor substrate and the basic layer is on or above the buffer layer, and wherein a portion of the buffer layer fills in or in between the micro-structures.

In one embodiment, the ohmic contact is formed by an alloy or a mutual inter-doping region between the buffer layer and the semiconductor substrate.

In one embodiment, the conductive layer further comprises a barrier layer which is formed between the basic layer and the buffer layer.

In one embodiment, the barrier layer is made of metal, a mixture of metals, or a metal compound.

In one embodiment, the buffer layer is made of a material selected from a IV group element, a mixture of IV group elements, a compound of a IV group element, metal, a mixture of metals, or a metal compound.

In one embodiment, the conductive layer or the basic layer includes a conductive material which is metal, a metal compound, a conductive polymer, or polysilicon.

In one embodiment, each of the micro-structures is a micro-recess or a micro-protrusion which has a size smaller than 10 μm.

In one embodiment, each of the micro-structures has a geometric shape which is cylindrical, rectangular/cubical, or conical.

In one embodiment, the micro-structures are distributed in an array form with a same or different density in different areas on the top surface.

In another perspective of the present invention, a semiconductor device is provided. The semiconductor device includes a first and a second ohmic contact structures, each comprising: a semiconductor substrate having a top surface which includes a plurality of micro-structures; and a conductive layer, formed on the micro-structures, wherein an ohmic contact is formed between the conductive layer and the semiconductor substrate; a current inflow end, coupled to the conductive layer of the first ohmic contact structure; and a current outflow end, coupled to the conductive layer of the second ohmic contact structure.

The objectives, technical details, features, and effects of the present invention will be better understood with regard to the detailed description of the embodiments below, with reference to the drawings.

### BRIEF DESCRIPTION OF THE DRAWINGS

FIG. 1 shows a prior art ohmic contact structure.

FIGS. 2A-2F show six embodiments of the ohmic contact structures according to the present invention.

FIG. 3 shows relations between germanium melting point and surface-to-bulk ratio.

FIGS. 4 and 5 show the ohmic contact structures according to two embodiments of the present invention.

FIG. 6 shows a semiconductor device according to another perspective of the present invention.

FIGS. 7A-7D show several examples of the layout of the micro-structures.

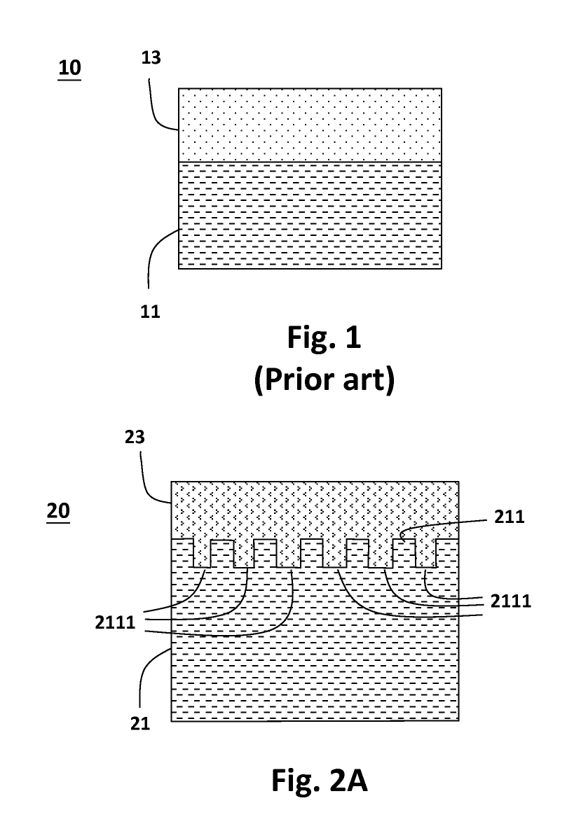

### DESCRIPTION OF THE PREFERRED EMBODIMENTS

The drawings as referred to throughout the description of the present invention are for illustrative purpose only, to show the interrelations between the regions and the process steps, but not drawn according to actual scale. The orientation wordings in the description such as: above, under, left, or right are for reference with respect to the drawings, but not for limiting the actual product made according to the present invention.

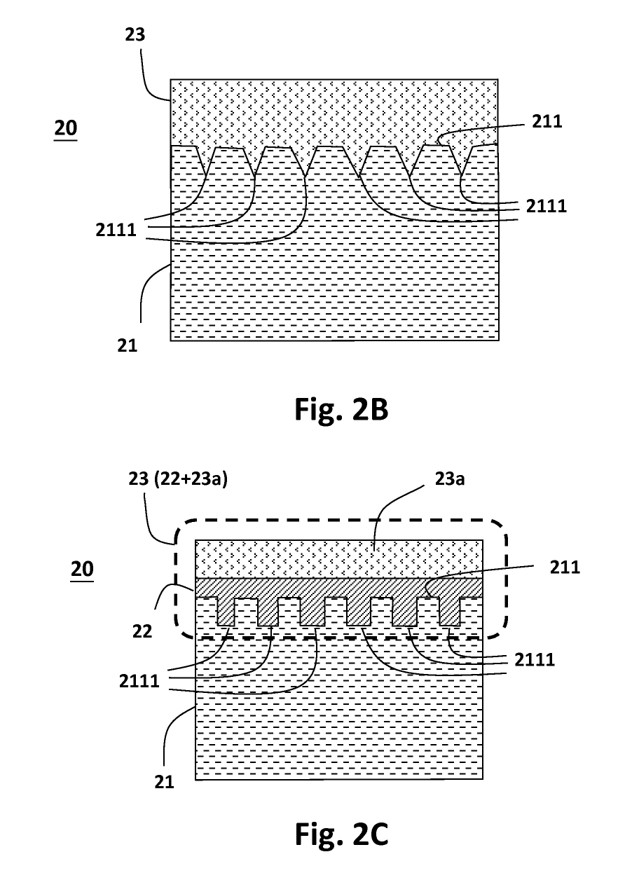

FIGS. 2A-2E show several embodiments of the ohmic contact structure 20 according to the present invention, wherein the ohmic contact structure 20 includes a semiconductor substrate 21 and a conductive layer 23. The semiconductor substrate 21 has a top surface 211, and the top surface 211 includes plural micro-structures 2111. In the embodiments of FIGS. 2A-2B, the conductive layer 23 and the semiconductor substrate 21 form an ohmic contact. A portion of the conductive layer 23 fills in or covers the micro-structures 2111 so that the conductive layer 23 is in close contact with the top surface 211. The ohmic contact is formed by the conductive layer 23 and the semiconductor substrate 21. The conductive layer 23 and the semiconductor substrate 21 can be coupled to external circuits respectively, for receiving or outputting a current, voltage, or other signal.

The micro-structures for example can be micro-recesses for example as shown in FIGS. 2A-2C, which can be formed by for example but not limited to lithographic and etching processes. Referring to the ohmic contact structures 20 shown in FIGS. 2A and 2B, the geometric shape of the micro-structures 2111 (micro-recesses) for example can be cylindrical, rectangular/cubical, or conical, and a portion of the conductive layer 23 fills in the micro-recesses. Or, the micro-structures can be micro-protrusions for example as shown in FIGS. 2D-2F, which can be but not limited to nanocrystals or quantum dots. Likely, the geometric shape of the micro-structures 2111 (micro-protrusions) for example can be cylindrical, rectangular/cubical, or conical. A portion of the conductive layers 23 covers the micro-protrusions and fills in between the micro-protrusions. The density of the micro-structures 2111 can be decided according to physical or process requirement, for example, according to the thermal expansion coefficients of the semiconductor substrate 21 and the conductive layer 23.

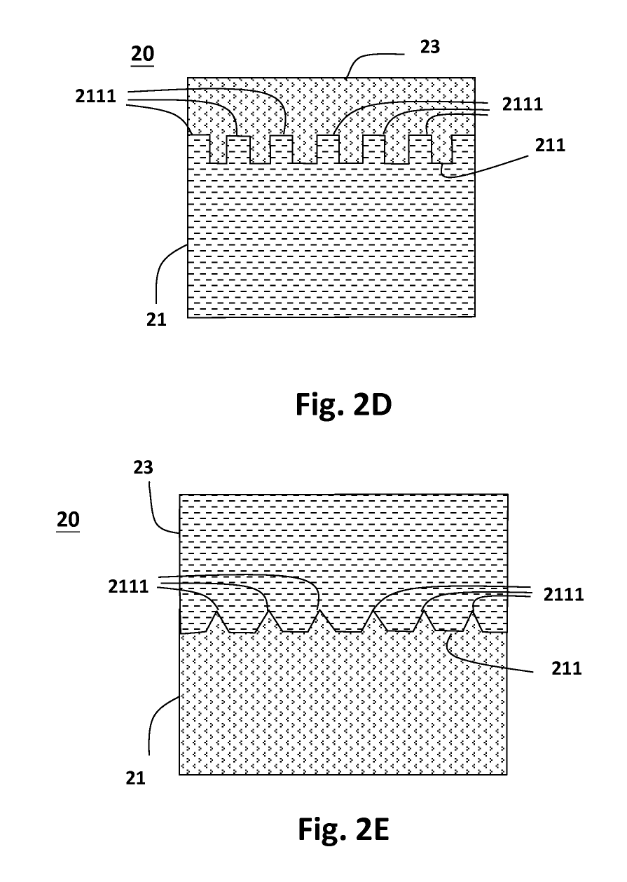

FIGS. 2C and 2F shows two embodiments of the present invention which are different from the embodiments of FIGS. 2A-2B and 2D-2E in that the conductive layer 23 further includes, in addition to a basic layer 23a, a buffer layer 22 formed on the semiconductor substrate 21, wherein a portion of the buffer layer 22 fills in or covers the micro-structure 2111 so that the buffer layer 22 is in close contact with the top surface 211 (FIG. 2C), or wherein a portion of the buffer layer 22 fills in between the micro-structure 2111 so that the buffer layer 22 is in close contact with the top surface 211 (FIG. 2F). It is found in the present invention that, when the material used for the buffer layer 22 is germanium and the size of each micro-structure 2111 is very small (for example, in a scale from several μm to several nm), the melting point is significantly different at different surface-to-bulk ratio (a quotient of surface area divided by volume). Referring to FIG. 3 wherein the horizontal coordinate indicates the surface-to-bulk ratio by a unit of nm⁻¹, the melting point significantly decreases when the surface-to-bulk ratio increases (i.e., as the size becomes smaller), and the difference can be as high as 200° K. The curves S1 and S2 respectively show the relationships between the melting points and the surface-to-bulk ratios under different stresses. The curve S2 (higher stress case) shows that the melting point decreases more rapidly as the surface-to-bulk ratio increases as compared with the curve S1 (lower stress case). It is found in the present invention that the micro-structures 2111 greatly help to reduce the temperature required for forming the ohmic contact.

More specifically, the thermal expansion coefficient of germanium is 5.8×10⁻⁶° C.⁻¹; the thermal expansion coefficient of silicon is 2.6×10⁻⁶° C.⁻¹; and the thermal expansion coefficient of silicon dioxide is 5×10⁻⁷° C.⁻1. When the temperature changes and the buffer layer 22 is made of germanium, the thermal expansion differences between the micro-structures 2111 and the material filling or covering the micro-structures will cause variations in stress; that is, similar to ice, as the stress is higher, the melting point decreases more. When the buffer layer 22 and the micro-structure 2111 begin to melt in their interface, an alloy or a mutual inter-doping region is formed between the buffer layer 22 and the semiconductor substrate 21, which is a major cause for forming the ohmic contact between the buffer layer 22 and the semiconductor substrate 21. According to the present invention, the micro-structures 2111 help to reduce the temperature required for forming the ohmic contact. The necessary temperature for forming the ohmic contact can be much reduced because of the micro-structures 2111, which is one of the major reasons for disposing the micro-structures 2111. Because the micro-structures 2111 are distributed on the top surface 211, the local melting point around the micro-structures 2111 decreases, which causes the global melting point to greatly decrease, and therefore the ohmic contact can be more easily formed between the buffer layer 22 and the semiconductor substrate 21 without requiring to heat the complete buffer layer 22 up to the melting point.

The micro-recesses or micro-protrusions can be designed according to thermal expansion coefficients of the neighboring materials; for example, the material with the higher thermal expansion coefficient can be designed to have the micro-recesses; this arrangement can better decrease the melting point and also reduce a thermal deformation at the interface. As a more specific example, at the interface between germanium and silicon, the micro-protrusions can be arranged at the germanium side and the micro-recesses can be arranged at the silicon side. However, the above arrangement is only an example and the present invention is not limited to the above-mentioned embodiment. By the aforementioned design of the micro-structures 2111, the temperature required for forming the ohmic contact in the semiconductor structure can be reduced to as low as 400° C. (673° K), which is much lower than the prior art. Besides, the process complexity and equipment specification requirement for forming such ohmic contact structure are much reduced according to the present invention. Please note that although the above explanation is referring to the embodiments of FIGS. 2C and 2F, the same principle applies to the other embodiments.

In the aforementioned embodiments, the size of each micro-recess or micro-protrusion is preferably smaller than 10 μm. In a more preferable embodiment, the size of each micro-recess or the micro-protrusion is preferably in nanometer scale, that is, smaller than 1 μm and even more preferably smaller than 100 nm. As the size is smaller, the melting point decreases more and is therefore better.

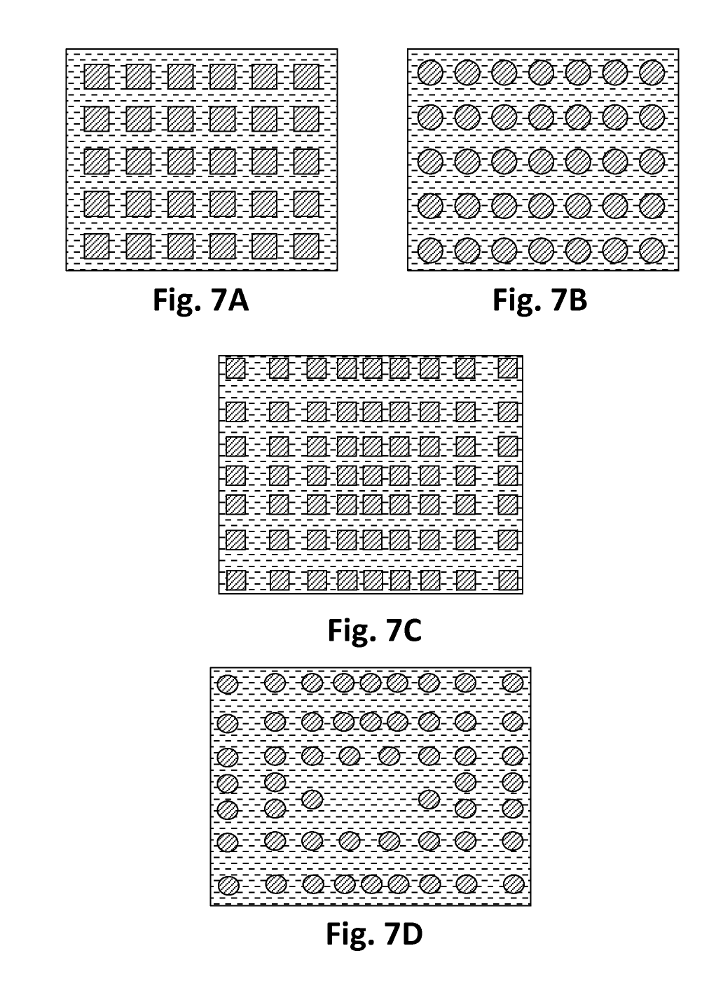

As explained in the above, the geometric shape of the micro-structures 2111 for example can be cylindrical, rectangular/cubical, or conical. The geometric shapes of the micro-structures 2111 can be designed according to physical or process requirements such as according to stress, alloy ratio/structure, or doping effect. The micro-structures can be distributed on the top surface 21 in an array form with the same or different density in different areas (for example, denser at the central region and looser at the peripheral region, or looser at the central region and denser at the peripheral region, or any regular or irregular distribution). FIGS. 7A-7D show several examples.

In one embodiment, the conductive layer 23 or the basic layer 23a is made of a conductive material such as metal (such as aluminum, copper, etc.), a metal compound, a conductive polymer, or polysilicon. In one embodiment, the buffer layer is made of a material selected from a IV group element (such as silicon, germanium, etc.), a mixture of IV group elements, a compound of a IV group element, metal (such as titanium, etc.), a mixture of metals, or a metal compound.

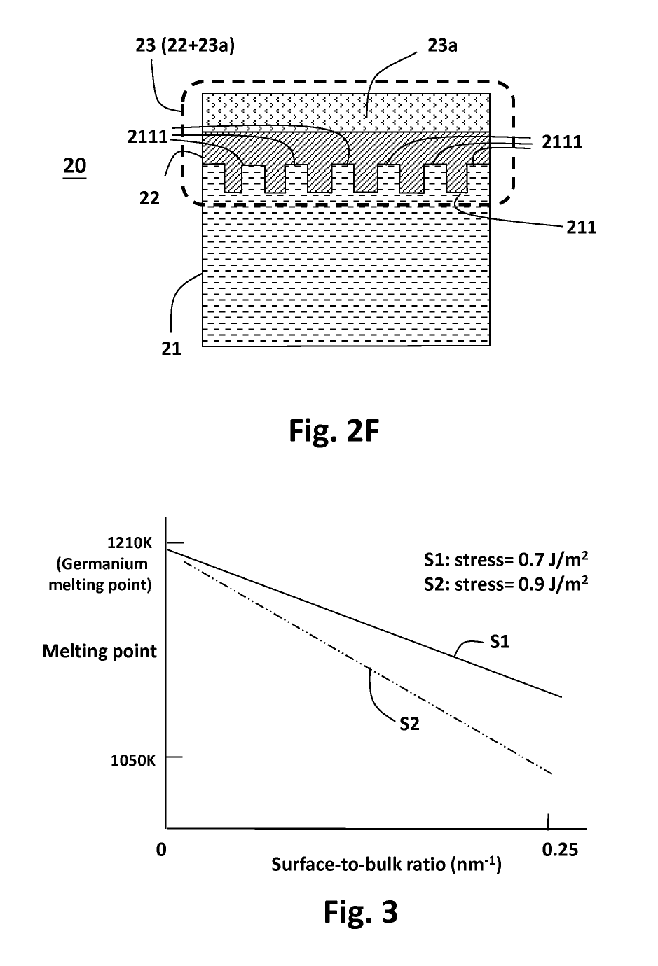

FIG. 4 shows a semiconductor structure 40 according to another embodiment of the present invention. Compared with FIG. 2A, the semiconductor structure 40 further includes a barrier layer 44 made of metal, a mixture of metals, or a metal compound. The metal for example can be titanium, tungsten, etc. which has an effect of blocking the conductive layer from diffusion.

Please refer to FIGS. 2A-2F and 4, the semiconductor substrate 21 for example can be a semiconductor substrate doped with conductive impurities. When the ohmic contact structures 20 and 40 are used for example in a GaN Schottky diode, the semiconductor substrate for example can be made of N type Gallium nitride (GaN). However, the above is only one example and the present invention is not limited to it. The semiconductor substrate 21 can be or include a silicon substrate doped with conductive impurities, and the ohmic contact structures 20 and 40 can be used in contacts or other electrical connections (such as for contacting or in the drain or source of an MOS transistor). The present invention can be applied to any semiconductor device in which it is required to form an ohmic contact.

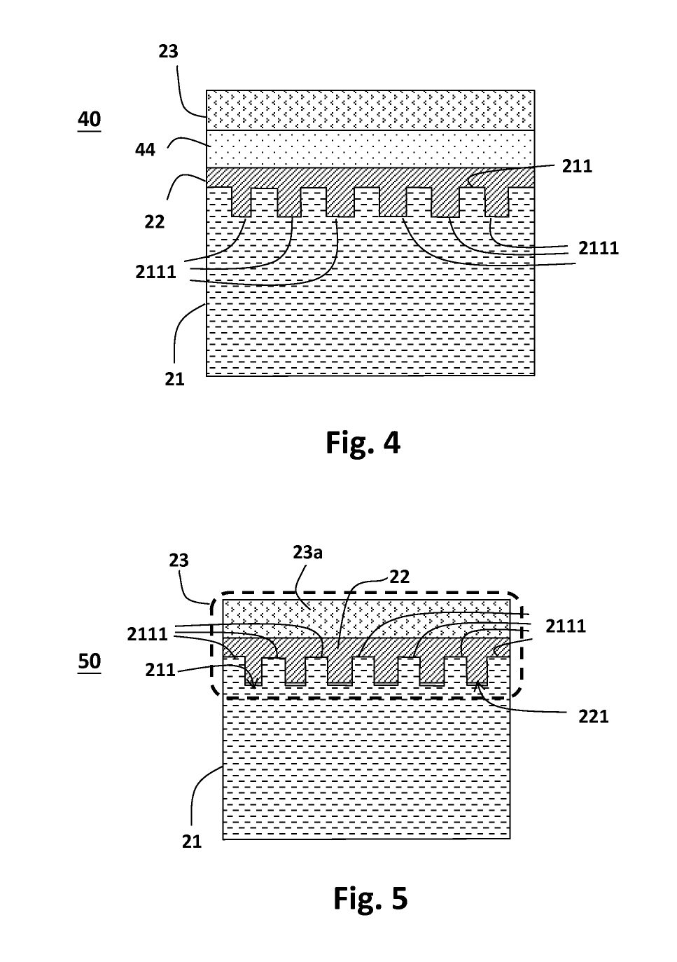

FIG. 5 shows an ohmic contact structure 50 according to another embodiment of the present invention. In this embodiment, the micro-structures 2111 are micro-protrusions evenly distributed on the top surface 211, but the micro-structures 2111 can be micro-recesses or distributed otherwise. The conductive layer 23 includes a basic layer 23a, and a buffer layer 22 formed on the semiconductor substrate 21. Due to size or density of the micro-structures 2111, the lowermost surface 221 of the buffer layer 22 is not completely in contact with the top surface 211, but a ohmic contact can still be formed between the conductive layer 23 and the semiconductor substrate 21. This embodiment shows that it is not exactly necessary for the conductive layer 23 to be completely in contact with the semiconductor substrate 21 at every local area.

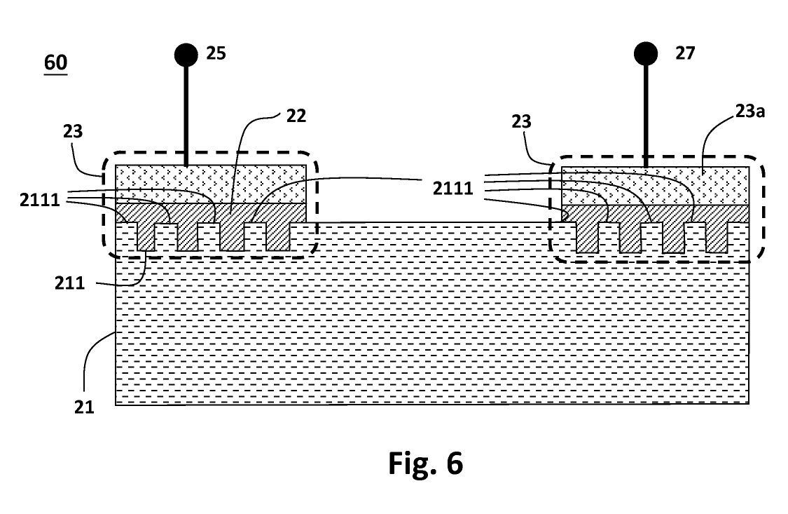

FIG. 6 shows a semiconductor device 60 according to another embodiment of the present invention. The semiconductor device 60 includes a semiconductor substrate 21, a plurality of micro-structures 2111, a conductive layer 23, an input terminal 25, a conductive layer 24, and an output terminal 27. The semiconductor substrate 21, the micro-structures 2111, and the conductive layer 23 at the left side form an ohmic contact structure which is for example similar to the embodiment shown in FIG. 2C, and similarly, the semiconductor substrate 21, the micro-structures 2111, and the conductive layer 23 at the right side also form an ohmic contact structure. A current inflow end 25 is electrically connected to the conductive layer 23 at the left side. A current outflow end 27 is electrically connected to the conductive layer 23 at the right side. The semiconductor device 60 for example can be, but not limited to, a Schottky diode, wherein the semiconductor substrate 21 for example can be but not limited to an N-type gallium nitride layer, and the buffer layer 22 for example can be made of but not limited to germanium. In another embodiment, the semiconductor device 60 can be another type of semiconductor device; for example, the semiconductor device 60 can forma transistor if a control terminal (not shown) is provided.

The present invention has been described in considerable detail with reference to certain preferred embodiments thereof. It should be understood that the description is for illustrative purpose, not for limiting the scope of the present invention. Those skilled in this art can readily conceive variations and modifications within the spirit of the present invention. Therefore, all these and other modifications should fall within the scope of the present invention. An embodiment or a claim of the present invention does not need to attain or include all the objectives, advantages or features described in the above. The abstract and the title are provided for assisting searches and not to be read as limitations to the scope of the present invention.

What is claimed is:

1. An ohmic contact structure, comprising:
a semiconductor substrate having a top surface which includes a plurality of micro-structures; and
a conductive layer, formed on the micro-structures,
wherein an ohmic contact is formed by the conductive layer and the semiconductor substrate.

2. The ohmic contact structure of claim 1, wherein the conductive layer comprises: a basic layer and a buffer layer, wherein the buffer layer is formed on the semiconductor substrate and the basic layer is on or above the buffer layer, and wherein a portion of the buffer layer fills in or in between the micro-structures.

3. The ohmic contact structure of claim 2, wherein the ohmic contact is formed by an alloy or a mutual inter-doping region between the buffer layer and the semiconductor substrate.

4. The ohmic contact structure of claim 2, wherein the conductive layer further comprises a barrier layer which is formed between the basic layer and the buffer layer.

5. The ohmic contact structure of claim 3, wherein the barrier layer is made of metal, a mixture of metals, or a metal compound.

6. The ohmic contact structure of claim 2, wherein the buffer layer is made of a material selected from a IV group element, a mixture of IV group elements, a compound of a IV group element, metal, a mixture of metals, or a metal compound.

7. The ohmic contact structure of claim 1, wherein the conductive layer includes a conductive material which is metal, a metal compound, a conductive polymer, or polysilicon.

8. The ohmic contact structure of claim 1, wherein each of the micro-structures has a size which is smaller than 10 μm.

9. The ohmic contact structure of claim 1, wherein the micro-structures are micro-recesses or micro-protrusions.

10. The ohmic contact structure of claim 1, wherein each of the micro-structures has a geometric shape which is cylindrical, rectangular/cubical, or conical.

11. The ohmic contact structure of claim 1, wherein the micro-structures are distributed in an array form with a same or different density in different areas on the top surface.

12. A semiconductor device, comprising:
a first and a second ohmic contact structures, each comprising:
a semiconductor substrate having a top surface which includes a plurality of micro-structures; and
a conductive layer, formed on the micro-structures;
wherein an ohmic contact is formed between the conductive layer and the semiconductor substrate;
a current inflow end, coupled to the conductive layer of the first ohmic contact structure; and
a current outflow end, coupled to the conductive layer of the second ohmic contact structure.

13. The semiconductor device of claim 12, wherein the conductive layer comprises: a basic layer and a buffer layer, wherein the buffer layer is formed on the semiconductor substrate and the basic layer is on or above the buffer layer, and wherein a portion of the buffer layer fills in or in between the micro-structures.

14. The semiconductor device of claim 13, wherein the ohmic contact is formed by an alloy or a mutual inter-doping region between the buffer layer and the semiconductor substrate.

15. The semiconductor device of claim 12, wherein the conductive layer further comprises a barrier layer which is formed between the basic layer and the buffer layer.

16. The semiconductor device of claim 12, wherein each of the micro-structures has a size which is smaller than 10 μm.

17. The semiconductor device of claim 12, wherein the micro-structures are micro-recesses or micro-protrusions

18. The semiconductor device of claim 12, wherein the micro-structures are distributed an array form with a same or different density in different areas on the top surface.
